(19) United States
(12) Patent Application Publication
(10) Pub. No.: US 2010/0269903 A1
(43) Pub. Date: Oct. 28, 2010

(54) PROCESS FOR PRODUCING POLYCRYSTALLINE SILICON SUBSTRATE AND POLYCRYSTALLINE SILICON SUBSTRATE

(75) Inventors: Masato Tsuchiya, Gunma (JP); Ikuo Mashimo, Gunma (JP); Yoshimichi Kimura, Tokyo (JP); Takehisa Kato, Saitama (JP); Masahiko Kakizawa, Tokyo (JP)

Correspondence Address: MARGER JOHNSON & MCCOLLOM, P.C., 210 SW MORRISON STREET, SUITE 400, PORTLAND, OR, 97204, US

(73) Assignees: MIMASU SEMICONDUCTOR INDUSTRY CO., LTD., Gunma (JP); WAKO PURE CHEMICAL INDUSTRIES, LTD., Osaka (JP)

(21) Appl. No.: 12/745,521

(22) PCT Filed: Nov. 28, 2008
(86) PCT No.: PCT/JP2008/071615

§ 371 Date: May 28, 2010

(30) Foreign Application Priority Data
Dec. 4, 2007 (JP) 2007-313430

(51) Int. Cl. H01L 31/0368; H01L 21/306

(52) U.S. Cl. 136/258; 438/753; 257/E21.219; 257/E31.043

(57) ABSTRACT

Provided are: a safe, low-cost method of producing a polycrystalline silicon substrate excellent in photoelectric conversion efficiency by which a uniform, fine uneven structure suited to a solar cell can be simply formed on the surface of the polycrystalline silicon substrate; and a polycrystalline silicon substrate having a uniform, fine, pyramid-shaped uneven structure so that its reflectance can be significantly reduced. The uneven structure is formed on the surface of the polycrystalline silicon substrate by etching the polycrystalline silicon substrate with an alkaline etching solution containing at least one kind selected from the group consisting of a carboxylic acid having 1 or more and 12 or less carbon atoms and each having at least one carboxyl group in one molecule, and salts of the acids.

### TECHNICAL FIELD

The present invention relates to a method of producing a polycrystalline silicon substrate having an uneven structure suitably used in, for example, a solar cell and a polycrystalline silicon substrate.

### BACKGROUND ART

A method involving forming an uneven structure on the surface of a silicon substrate so that light incident on the surface may be efficiently taken in the substrate has been conventionally employed for improving the efficiency of a solar cell. A single crystal silicon substrate that facilitates the improvement in efficiency has been widely used as the silicon substrate. For example, Non-patent Document 1 discloses a method involving subjecting the surface of a single crystal silicon substrate having a (100) plane on the surface to an anisotropic etching treatment with an aqueous solution of a mixture of sodium hydroxide and isopropyl alcohol to form pyramid-shaped (quadrangular pyramid) unevenness constituted of a (111) plane. In addition, Patent Document 1 reports an alkaline etching solution containing at least one kind selected from the group consisting of carboxylic acids each having 12 or less carbon atoms and each having at least one carboxyl group in one molecule, and salts of the acids as an etching solution that enables uniform formation of a fine uneven structure of a desired size suited to a solar cell on the surface of a single crystal silicon substrate excellent in photoelectric conversion efficiency.

Single crystal silicon substrates each involve such a problem that a production cost is high, and in recent years, polycrystalline silicon substrates have started to be used for the purpose of a cost reduction. However, the polycrystalline silicon substrates are each such that the plane orientation of a crystal is irregular, and hence it is difficult to reduce the reflectance of the entirety of each of the substrates only by an etching treatment with an alkaline aqueous solution. For example, a method involving performing etching with an alkaline aqueous solution to remove a damaged layer on the surface of any such polycrystalline silicon substrate and forming fine unevenness by a dry etching method or the like after the removal (see, for example, Patent Document 2) and a method involving performing dry etching and wet etching (Patent Document 3) have been known. However, the methods each involve the following problem. That is, the methods each require a complicated operation.

### Patent Document 1: WO 2006/046601 A1

### Patent Document 2: JP 2004-235274 A

### Patent Document 3: JP 2000-101111 A

### Non-patent Document 1: Progress in Photovoltaics: Research and Applications, Vol. 4, 435-438 (1996).

### DISCLOSURE OF THE INVENTION

### Problems to be Solved by the Invention

An object of the present invention is to provide a safe, low-cost method of producing a polycrystalline silicon substrate excellent in photoelectric conversion efficiency by which a uniform, fine uneven structure suited to a solar cell can be simply formed on the surface of the polycrystalline silicon substrate, a polycrystalline silicon substrate having a uniform, fine, pyramid-shaped uneven structure so that its reflectance can be significantly reduced, and an etching method by which a polycrystalline silicon substrate having a uniform, fine uneven structure so that its reflectance can be significantly reduced can be simply produced.

### Means for Solving the Problems

The inventors of the present invention have made extensive studies to solve the above-mentioned problems. As a result, to their surprise, the inventors have found that the use of an alkaline aqueous solution containing a carboxylic acid as an etching solution can result in efficient, stable formation of a uniform, fine uneven structure not only on a single crystal silicon substrate but also on a polycrystalline silicon substrate, and hence a polycrystalline silicon substrate having a low reflectance can be simply obtained at a low cost.

That is, a method of producing a polycrystalline silicon substrate of the present invention is characterized by including etching a polycrystalline silicon substrate with an alkaline etching solution containing at least one kind selected from the group consisting of a carboxylic acid having 1 or more and 12 or less carbon atoms and each having at least one carboxyl group in one molecule, and salts of the acids to form an uneven structure on the surface of the polycrystalline silicon substrate.

The etching solution preferably contains silicon, or more preferably contains silicon at a 0.5 mass % concentration to a saturated concentration. A method of incorporating silicon into the etching solution is suitably such that one or more kinds of silicon selected from the group consisting of metal silicon, silica, silicic acid, and silicate are dissolved in advance.

The carboxylic acid is preferably at least one kind selected from the group consisting of acetic acid, propionic acid, butanoic acid, pentanoic acid, hexanoic acid, heptanoic acid, octanoic acid, nonanoic acid, decanoic acid, undecanoic acid, dodecanoic acid, acrylic acid, oxalic acid, citric acid, malic acid, and cyclopentane dicarboxylic acid. Further, the carboxylic acid suitably has 2 or more and 8 or less carbon atoms. The etching solution preferably has a carboxylic acid concentration of 0.2 to 80 mass %.

A polycrystalline silicon substrate of the present invention is a polycrystalline silicon substrate having an uneven structure on its surface produced by the production method of the present invention. The polycrystalline silicon substrate of the present invention is suitably used as a semiconductor substrate for a solar cell.

A method of etching a polycrystalline silicon substrate of the present invention is characterized by including etching a polycrystalline silicon substrate with an alkaline etching solution containing at least one kind selected from the group consisting of carboxylic acids each having 1 or more and 12 or less carbon atoms and each having at least one carboxyl group in one molecule, and salts of the acids.

The etching solution preferably contains silicon.

### EFFECTS OF THE INVENTION

According to the methods of producing and etching a polycrystalline silicon substrate of the present invention, the polycrystalline silicon substrate being excellent in photoelectric conversion efficiency, having a uniform, fine uneven structure of a desired size suited to a solar cell, and having an extremely low reflectance can be produced safely and efficiently at a low cost, and simply and stably without any need for a complicated operation such as dry etching. The polycrystalline silicon substrate of the present invention has a uniform, fine uneven structure suited to a solar cell or the like, and has a significantly reduced reflectance. The polycrystalline silicon substrate can be used to provide a solar cell excellent in photoelectric conversion efficiency.

### BRIEF DESCRIPTION OF THE DRAWINGS

FIG. 1 is photographs showing the results of electron microscope photographs of Example 1.

FIG. 2 is photographs showing the results of electron microscope photographs of Comparative Example 1.

### BEST MODE FOR CARRYING OUT THE INVENTION

Hereinafter, embodiments of the present invention are described with reference to the attached drawings. However, the examples shown in the figures are given for illustrative purposes, and it is needless to say that various modifications may be made without departing from the technical idea of the present invention.

A method of producing a polycrystalline silicon substrate of the present invention involves using, as an etching solution, an alkaline solution containing at least one kind of carboxylic acids each having 12 or less carbon atoms and each having at least one carboxyl group in one molecule, and salts of the acids, and etching the surface of a polycrystalline silicon substrate by soaking the substrate in the etching solution, to thereby form a uniform, fine uneven structure on the surface other than a (111) plane of the substrate. According to the present invention, a uniform, fine, pyramid-shaped uneven structure can be formed on each of (100) and (110) planes, and hence a reflectance can be significantly reduced.

As the carboxylic acid, it is possible to use a wide range of known organic compounds each having 12 or less carbon atoms and each having at least one carboxyl group in one molecule. The number of carboxyl groups is not particularly limited. However, a monocarboxylic acid, a dicarboxylic acid, and a tricarboxylic acid having 1 to 3 carboxyl groups are preferred. The number of carbons in the carboxylic acid is 1 or more, preferably 2 or more, or more preferably 4 or more, and 12 or less, preferably 10 or less, or more preferably 8 or less. Any one of a chain carboxylic acid and a cyclic carboxylic acid may be used as the carboxylic acid, and a chain carboxylic acid is preferred. In particular, a chain carboxylic acid having 2 to 8 carbon atoms is preferred, and a chain carboxylic acid having 4 to 8 carbon atoms is more preferred.

Examples of the chain carboxylic acid include: saturated chain monocarboxylic acids (saturated fatty acids) such as formic acid, acetic acid, propanoic acid, butanoic acid, pentanoic acid, hexanoic acid, heptanoic acid, octanoic acid, nonanoic acid, decanoic acid, undecanoic acid, dodecanoic acid, and isomers thereof; aliphatic saturated dicarboxylic acids such as oxalic acid, malonic acid, succinic acid, glutaric acid, adipic acid, pimelic acid, and isomers thereof; aliphatic saturated tricarboxylic acids such as propane tricarboxylic acid and methane triacetic acid; unsaturated fatty acids such as acrylic acid, butenoic acid, pentenoic acid, hexenoic acid, heptenoic acid, pentadienoic acid, hexadienoic acid, heptadienoic acid, and acetylene carboxylic acid; aliphatic unsaturated dicarboxylic acids such as butenedioic acid, pentenedioic acid, hexenedioic acid, hexenedioic acid, and acetylene dicarboxylic acid; and aliphatic unsaturated tricarboxylic acids such as aconitic acid.

Examples of the cyclic carboxylic acid include: alicyclic carboxylic acids such as cyclopropane carboxylic acid, cyclobutane carboxylic acid, cyclopentane carboxylic acid, hexahydrobenzoic acid, cyclopropane dicarboxylic acid, cyclobutane dicarboxylic acid, cyclopentane dicarboxylic acid, cyclopropane tricarboxylic acid, and cyclobutane tricarboxylic acid; and aromatic carboxylic acids such as benzoic acid, phthalic acid, and benzene tricarboxylic acid.

In addition, carboxyl group-containing organic compounds each having a functional group other than a carboxyl group can also be used. Examples thereof include: oxycarboxylic acids such as glycolic acid, lactic acid, hydroacrylic acid, oxybutyric acid, glyceric acid, tartronic acid, malic acid, tartaric acid, citric acid, salicylic acid, and gluconic acid; ketocarboxylic acids such as pyruvic acid, acetoacetic acid, propionylacetic acid, and levulinic acid; and alkoxycarboxylic acids such as methoxycarboxylic acid and ethoxyacetic acid.

Of those carboxylic acids, saturated chain monocarboxylic acids, aliphatic saturated dicarboxylic acids, unsaturated fatty acids, alicyclic carboxylic acids, and oxycarboxylic acids are preferred. Particularly preferred examples of the carboxylic acids include acetic acid, propionic acid, butanoic acid, pentanoic acid, hexanoic acid, heptanoic acid, octanoic acid, nonanoic acid, decanoic acid, undecanoic acid, dodecanoic acid, acrylic acid, oxalic acid, citric acid, malic acid, and cyclopentane dicarboxylic acid.

One kind of such carboxylic acids as described above can be used as the carboxylic acid in the etching solution, or two or more kinds of them can be appropriately used in combination as the carboxylic acid. It is preferred that two or more kinds of them be used in combination. When two or more kinds of carboxylic acids are used in combination, the following combination is suited. That is, at least one kind of carboxylic acid having 4 to 8 carbon atoms is used as a main component, and a carboxylic acid having 3 or less carbon atoms or a carboxylic acid having 9 or more carbon atoms is further incorporated.

The concentration of the carboxylic acid in the etching solution is preferably 0.2 to 80 mass %, or more preferably 1 to 40 mass %.

In the production method of the present invention, the size of an uneven structure to be formed on the surface of the polycrystalline silicon substrate can be varied by selecting a predetermined carboxylic acid. In particular, the size of pyramid-shaped protrusions of the uneven structure on the surface of the substrate can be regulated by using an etching solution mixed with a plurality of carboxylic acids having different carbon numbers. As the carbon number in the carboxylic acid to be added is smaller, the size of the uneven structure becomes smaller. In order to uniformly form fine unevenness, it is preferred to contain one or two or more kinds of aliphatic carboxylic acids having 2 to 8, or preferably 4 to 8, carbon atoms as main components, and if required, other carboxylic acids.

In addition, when, at the time of the etching of the polycrystalline silicon substrate, the contamination of the semiconductor substrate with a metal impurity (the adsorption of the metal impurity to the surface of the semiconductor substrate) can be effectively suppressed, the generation efficiency of a solar cell produced by using the resultant polycrystalline silicon substrate can be improved. For such purpose, two or more kinds, that is, a dicarboxylic acid represented by the following general formula (1) or a salt of the acid (hereinafter abbreviated as “the dicarboxylic acid or the salt of the acid according to the present invention”) and any one of the carboxylic acids except the foregoing are preferably used in combination.

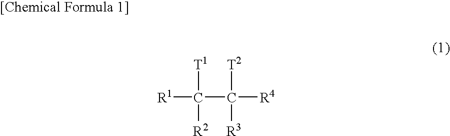

(In the general formula (1): T¹ and T² each independently represent a hydrogen atom, a hydroxyl group, a carboxyl group, or an alkyl group having 1 to 3 carbon atoms, or T¹ and T² together form a bond; and R¹ to R⁴ each independently represent a hydrogen atom, a hydroxyl group, a carboxyl group, or an alkyl group having 1 to 3 carbon atoms, provided that, when T¹ and T² do not together form a bond, any two of T¹, T² and R¹ to R⁴ each represent a carboxyl group, and any one of the remainder represents a hydroxyl group, and the others each independently represent a hydrogen atom or an alkyl group having 1 to 3 carbon atoms, and when T¹ and T² together form a bond, any two of R¹ to R⁴ each represent a carboxyl group, and the others each independently represent a hydrogen atom or an alkyl group having 1 to 3 carbon atoms.)

In the general formula (1), the alkyl group having 1 to 3 carbon atoms represented by each of T¹ and T² may be linear, branched, or cyclic, and examples of the group include a methyl group, an ethyl group, an n-propyl group, an isopropyl group, and a cyclopropyl group. Of those, a methyl group is preferred.

In addition, in the general formula (1), the alkyl group having 1 to 3 carbon atoms represented by each of R¹ to R⁴ may be linear, branched, or cyclic, and examples of the group include a methyl group, an ethyl group, an n-propyl group, an isopropyl group, and a cyclopropyl group. Of those, a methyl group is preferred.

In the general formula (1), the phrase “T¹ and T² together form a bond” means that a double bond is formed between two carbon atoms (C) in the general formula (1).

Therefore, the dicarboxylic acids or the salts of the acids according to the present invention can be classified into two cases where a double bond is formed between two carbon atoms in the general formula (1) and where a single bond is formed between the two carbon atoms.

Of the dicarboxylic acids or the salts of the acids according to the present invention, the one in which a double bond is formed between two carbon atoms (C) includes a dicarboxylic acid represented by the following general formula (2):

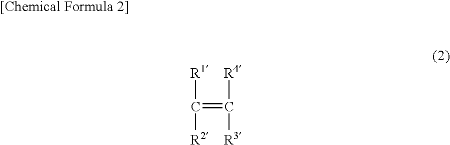

(In the general formula (2), R^{1′} to R^{4′} each independently represent a hydrogen atom, a carboxyl group, or an alkyl group having 1 to 3 carbon atoms, provided that any two of R^{1′} to R^{4′} each represent a carboxyl group, the others each independently represent a hydrogen atom or an alkyl group having 1 to 3 carbon atoms.)

It should be noted that, in the general formula (2), the alkyl group having 1 to 3 carbon atoms represented by each of R^{1′} to R^{4′} may be linear, branched, or cyclic, and examples of the group include a methyl group, an ethyl group, an n-propyl group, an isopropyl group, and a cyclopropyl group. Of those, a methyl group is preferred.

Of the dicarboxylic acids represented by the general formula (2) or the salts of the acids according to the present invention as described above, the one in which any one of R^{1′} and R^{2′} represents a carboxyl group, any one of R^{3′} and R^{4′} represents a carboxyl group, and the others each independently represent a hydrogen atom or an alkyl group having 1 to 3 carbon atoms in the general formula (2) is preferred.

In addition, in the general formula (2), as for the remaining two substituents other than carboxyl groups in R^{1′} to R^{4′}, the one in which at least one substituent represents a hydrogen atom and another substituent represents a hydrogen atom or an alkyl group having 1 to 3 carbon atoms is preferred. Of those, the one in which all of remaining two substituents each represent a hydrogen atom is particularly preferred.

Specific examples of the dicarboxylic acid represented by the general formula (2) or the salt of the acid according to the present invention as described above include fumaric acid, maleic acid, dimethylfumaric acid, dimethylmaleic acid, citraconic acid, mesaconic acid, ethylfumaric acid, and ethylmaleic acid. Of those, fumaric acid, maleic acid, citraconic acid, mesaconic acid, and the like are preferred, and fumaric acid and maleic acid are particularly preferred.

Of the dicarboxylic acid or the salts of the acids according to the present invention, the one in which a single bond is formed between two carbon atoms (C) includes a dicarboxylic acid represented by the following general formula (3).

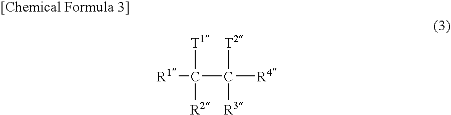

(In the general formula (3), T^{1″}, T^{2″} and R^{1″} to R^{4″} each independently represent a hydrogen atom, a hydroxyl group, a carboxyl group, or an alkyl group having 1 to 3 carbon atoms, provided that any two of T^{1″}, T^{2″} and R^{1″} to R^{4″} each represent a carboxyl group, any one of the remainder represents a hydroxyl group, and the others each independently represent a hydrogen atom or an alkyl group having 1 to 3 carbon atoms.)

It should be noted that, in the general formula (3), the alkyl group having 1 to 3 carbon atoms represented by each of T^{1″}, T^{2″} and R^{1″} to R^{4″} may be linear, branched, or cyclic, and examples of the group include a methyl group, an ethyl group, an n-propyl group, an isopropyl group, and a cyclopropyl group. Of those, a methyl group is preferred.

Of the dicarboxylic acids represented by the general formula (3) or the salts of the acids according to the present invention as described above, the one in which any one of T^{1″}, R^{1″}, and R^{2″} represents a carboxyl group, any one of T^{2″}, R^{3″}, and R^{4″} represents a carboxyl group, any one of the remainder represents a hydroxyl group, and the others each independently represent a hydrogen atom or an alkyl group having 1 to 3 carbon atoms in the general formula (3) is preferred.

In addition, in the general formula (3), as the remaining three substituents each of which is neither a carboxyl group nor a hydroxyl group among T^{1″}, T^{2″}, and R^{1″} to R^{4″}, it is preferred that all of the remaining three substituents each represent a hydrogen atom.

Specific examples of the dicarboxylic acid represented by the general formula (3) or the salt of the acid according to the present invention as described above include malic acid, 2,3,3-trimethylmalic acid, 2,3-dimethylmalic acid, 3,3-dimethylmalic acid, 2-methylmalic acid, and 3-methylmalic acid. Of those, malic acid and the like are preferred. It should be noted that, malic acid may be D-malic acid, L-malic acid, DL-malic acid, or a mixture of D-malic acid and L-malic acid with different mixing ratios.

Examples of the salt of the dicarboxylic acid or the salt of the acid according to the present invention include an alkali metal salt (a sodium salt, a potassium salt, a lithium salt, a cesium salt, and the like), an alkaline earth metal salt (a calcium salt, a magnesium salt, and the like), an ammonium salt, an alkylammonium salt (a tetramethylammonium salt, a tetraethylammonium salt, a tetrabutylammonium salt, and the like), and an alkali metal salt is preferred. It should be noted that, a transition metal salt (an iron salt, a copper salt, a cobalt salt, a nickel salt, and the like) is not preferred.

Of the dicarboxylic acids or the salts of the acids according to the present invention, the one selected from fumaric acid, maleic acid, citraconic acid, mesaconic acid, malic acid, and salts of the acids is particularly preferred.

It should be noted that one kind of the dicarboxylic acids or the salts of the acids according to the present invention may be used alone, or two or more kinds of them may be appropriately used in combination.

The concentration of the dicarboxylic acid or the salt of the acid according to the present invention in the etching solution is preferably 0.005 to 80 mass % or more preferably 0.1 to 20 mass %.

In addition, when two or more kinds, that is, the dicarboxylic acid or the salt of the acid according to the present invention and any one of the carboxylic acids except the foregoing are used in combination, the two or more kinds are appropriately selected so that the total concentration of the carboxylic acids in the etching solution, that is, the sum of the concentration of the dicarboxylic acid or the salt of the acid according to the present invention and the concentration of the carboxylic acid except the foregoing ranges from preferably 0.2 to 80 mass % or more preferably 1 to 40 mass %.

The etching solution used in the present invention suitably further contains silicon in addition to the above-mentioned carboxylic acid. The incorporation of silicon into the etching solution can additionally stabilize the pyramid shape formed on the silicon substrate.

Although a method of preparing the etching solution containing silicon is not particularly limited, it is preferred that metal silicon, silica, silicic acid, silicate, and the like be dissolved in advance so that the solution is caused to contain silicon. The concentration of silicon in the etching solution is preferably 0.5 mass % or more, or more preferably 2 mass % or more. An upper limit for the addition amount of silicon is not limited, and an etching solution containing silicon at a saturated concentration may be used.

The silicate is preferably a silicate of an alkali metal, and examples of the silicate include: sodium silicates such as sodium orthosilicate (Na₄SiO₄.nH₂O) and sodium metasilicate (Na₂SiO₃.nH₂O); potassium silicates such as K₄SiO₄.nH₂O and K₂SiO₃.nH₂O; and lithium silicates such as Li₄SiO₄.nH₂O and Li₂SiO₃.nH₂O.

The etching solution used in the present invention is an alkaline solution having a pH in excess of 7.0, and preferably has a pH of 13 or more.

The alkaline solution is, for example, an aqueous solution in which an alkali is dissolved. Each of an organic alkali and an inorganic alkali can be used as the alkali. The organic alkali is preferably, for example, a quaternary ammonium salt such as tetramethylammonium hydroxide. Preferred examples of the inorganic alkali include: hydroxides of alkali metals or alkaline earth metals such as sodium hydroxide, potassium hydroxide, and calcium hydroxide; alkali carbonates such as sodium carbonate and potassium carbonate; and ammonia. Of those, sodium hydroxide or potassium hydroxide is particularly preferred. One kind of those alkalis may be used alone, or two or more kinds of them may be used as a mixture. An alkali concentration in the etching solution is preferably 1 to 50 mass %, more preferably 3 to 30 mass %, or still more preferably 3 to 25 mass %.

In the present invention, the polycrystalline silicon substrate may be of each of a p-type and an n-type.

In the method of the present invention, a method for the etching treatment is not particularly limited, and a uniform, fine uneven structure is formed on the surface of the polycrystalline silicon substrate by, for example, soaking the polycrystalline silicon substrate in an etching solution heated to and held at a predetermined temperature for a predetermined time period. The temperature of the etching solution, which is not particularly limited, is preferably 70° C. to 98° C. The etching time, which is not particularly limited either, is suitably 15 to 30 minutes.

### EXAMPLES

Hereinafter, the present invention is described more specifically by way of examples. However, it should be appreciated that these examples are shown for illustrative purposes, and should not be interpreted in a limiting manner.

### Examples 1 to 21

A polycrystalline silicon wafer (150 mm×150 mm) was subjected to an etching treatment with each of aqueous solutions each having the composition shown in Table 1 as an etching solution under predetermined conditions (a temperature and a time) shown in Table 1 by using a dip-type etching machine (manufactured by Mimasu Semiconductor Industry Co., Ltd.). It should be noted that the composition of each etching solution was represented in a unit of mass % in Table 1.

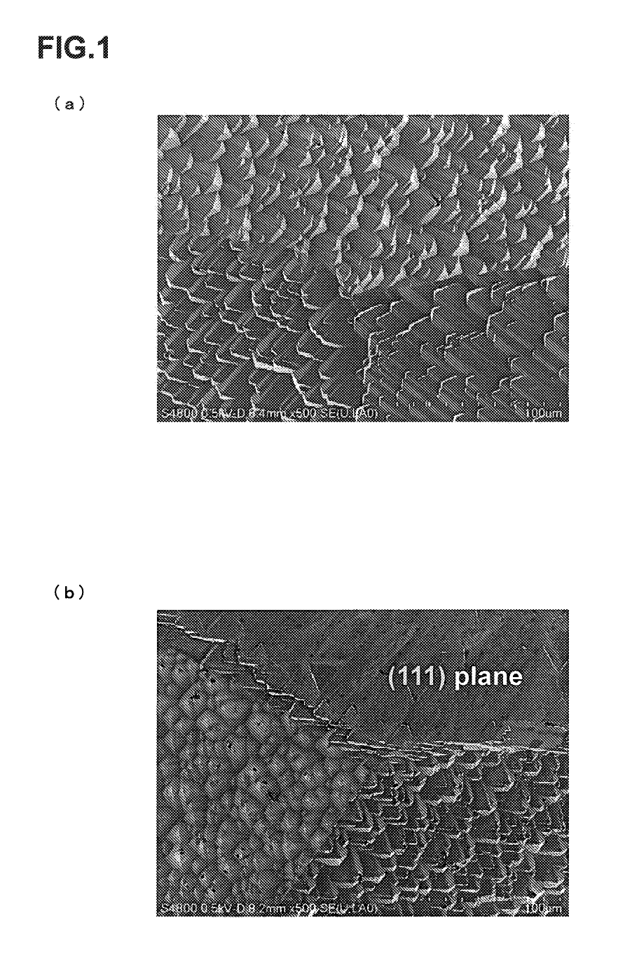

The surface of each silicon wafer after the etching treatment was observed with a scanning electron microscope. FIG. 1 is scanning electron microscope photographs (at a magnification of 500) of Example 1, and two representative points were selected in terms of an external appearance and subjected to measurement.

In addition, the reflectance of each polycrystalline silicon wafer after the etching treatment was measured. Table 2 shows the results of the measurement of the reflectance. Conditions for the measurement of the reflectance are as described below. A Lambda Ace VM-8000 (manufactured by DAINIPPON SCREEN MFG. CO., LTD.) was used as a reflectance-measuring apparatus, a circle having a diameter of 2 mm was defined as a measurement range, and wavelengths of 430 nm, 600 nm, and 760 nm were used as measurement wavelengths. Two representative points were selected as measurement sites in terms of an external appearance.

TABLE 1

| | Composition of etching solution | | | Conditions | |
|---|---|---|---|---|---|
| Example | | Carboxylic | Silicon | Temperature | Time |
| No. | Alkali | acid | compound | (° C.) | (minute(s)) |
| 1 | KOH 7.5% | Hexanoic acid(C6) | K₂SiO₃ 2.5% | 80 | 20 |
| | | 5% | | | |
| 2 | KOH 3% | Butanoic acid(C4) | None | 80 | 20 |
| | | 2% | | | |
| 3 | NaOH 8% | Hexanoic acid(C6) | K₂SiO₃ 0.5% | 80 | 20 |
| | | 5% | | | |
| 4 | TMAH 4% | Hexanoic acid(C6) | None | 80 | 20 |
| | | 5% | | | |
| 5 | Sodium | Propanoic acid(C3) | None | 80 | 60 |
| | carbonate | 0.5% | | | |
| | 8% | | | | |
| 6 | Ammonia | Heptanoic acid(C7) | None | 60 | 60 |
| | 10% | 4% | | | |
| 7 | KOH 25% | Butanoic acid(C4) | None | 80 | 20 |
| | | 2% | | | |
| 8 | KOH 30% | Acetic acid(C2) 1% | None | 70 | 5 |
| 9 | KOH 1% | Butanoic acid(C4) | None | 80 | 60 |
| | | 0.2% | | | |
| 10 | KOH 45% | Butanoic acid(C4) | None | 50 | 1 |
| | | 1% | | | |
| 11 | KOH 7% | Citric acid(C3) 4% | None | 80 | 20 |
| 12 | KOH 7% | Heptanoic acid(C7) | None | 80 | 20 |
| | | 4% | | | |
| 13 | KOH 7% | Decanoic acid(C10) | None | 80 | 20 |
| | | 0.3% | | | |
| 14 | KOH 7% | Cyclopentane | None | 80 | 20 |
| | | dicarboxylic | | | |
| | | acid(C7) 1% | | | |
| 15 | KOH 7% | Oxalic acid(C2) 2% | None | 80 | 20 |
| 16 | KOH 7% | Hexanoic acid(C6) | None | 80 | 20 |
| | | 5% + | | | |
| | | Malic acid(C4) | | | |
| | | 0.3% | | | |
| 17 | KOH 7% | Heptanoic acid(C7) | None | 80 | 20 |
| | | 4% + | | | |
| | | Malic acid(C4) | | | |
| | | 2% | | | |
| 18 | NaOH 8% | Butanoic acid(C4) | Si(dissolved) | 80 | 20 |
| | | 4% | 1% | | |
| 19 | NaOH 8% | Nonanoic acid(C9) | Sodium | 80 | 20 |
| | | 2% | orthosilicate | | |
| | | | 10% | | |
| 20 | KOH 5% | Citric acid(C3) 4% | Sodium | 80 | 20 |
| | | | metasilicate | | |
| | | | 4% | | |
| 21 | KOH5% | Citric acid(C3) 4% | Lithium | 80 | 20 |
| | | | silicate 1% | | |

TABLE 2

| Example | Reflectance (%) | | |
|---|---|---|---|
| No. | 430 nm | 600 nm | 760 nm |

| | | | | | | |
|---|---|---|---|---|---|---|
| 1 | 4.1 | 5.4 | 2.7 | 2.9 | 5.3 | 6.4 |
| 2 | 5.5 | 5.7 | 3.0 | 3.0 | 7.4 | 7.2 |
| 3 | 4.0 | 3.8 | 2.5 | 2.7 | 6.0 | 5.4 |
| 4 | 6.6 | 6.0 | 4.1 | 3.8 | 7.3 | 8.0 |
| 5 | 9.3 | 9.3 | 3.0 | 3.7 | 9.0 | 9.3 |
| 6 | 14.1 | 12.7 | 8.0 | 8.3 | 13.8 | 13.1 |
| 7 | 9.9 | 10.3 | 6.3 | 5.6 | 10.2 | 9.6 |
| 8 | 10.8 | 10.2 | 7.2 | 7.0 | 11.4 | 10.7 |
| 9 | 9.9 | 10.6 | 5.5 | 5.8 | 10.4 | 11.0 |
| 10 | 12.0 | 12.9 | 8.2 | 8.0 | 13.5 | 12.9 |
| 11 | 4.6 | 5.5 | 4.0 | 3.5 | 5.3 | 7.4 |
| 12 | 4.0 | 5.9 | 3.2 | 3.7 | 6.2 | 5.9 |
| 13 | 4.6 | 5.0 | 5.1 | 3.9 | 9.3 | 8.9 |
| 14 | 8.0 | 6.9 | 5.6 | 6.6 | 11.2 | 10.2 |
| 15 | 6.3 | 6.9 | 6.1 | 4.9 | 10.6 | 11.7 |
| 16 | 4.2 | 3.3 | 2.5 | 2.9 | 6.5 | 5.4 |
| 17 | 3.3 | 4.3 | 3.0 | 3.2 | 7.4 | 6.1 |
| 18 | 4.2 | 5.4 | 3.9 | 4.4 | 9.9 | 10.5 |
| 19 | 5.9 | 6.0 | 4.0 | 5.5 | 9.1 | 10.2 |
| 20 | 5.9 | 6.4 | 4.6 | 5.6 | 11.0 | 10.4 |
| 21 | 8.2 | 7.9 | 6.1 | 7.0 | 12.9 | 13.2 |

### Comparative Examples 1 to 8

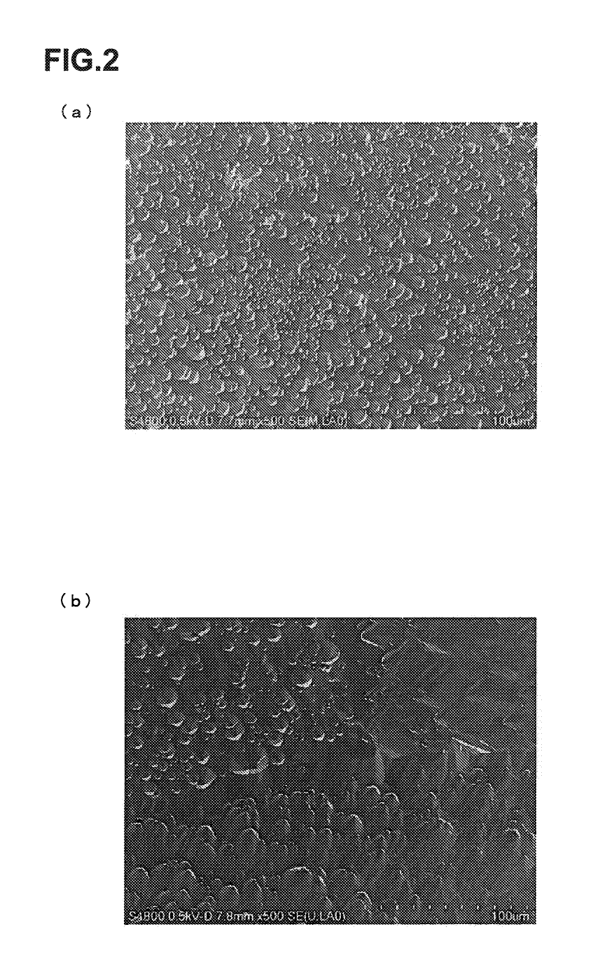

Polycrystalline silicon wafers were each subjected to an etching treatment in the same manner as in Example 1 except that each aqueous solution having the composition shown in Table 3 was used as an etching solution, and then observation with a scanning electron microscope and reflectance measurement were performed. It should be noted that the composition of each etching solution was represented in a unit of mass % in Table 3. FIG. 2 is scanning electron microscope photographs (at a magnification of 500) of Comparative Example 1, and two representative points were selected in terms of an external appearance and subjected to measurement. Table 4 shows the results of the measurement of the reflectance.

TABLE 3

| | Composition of etching solution | | | | Conditions | |
|---|---|---|---|---|---|---|
| Comparative | | Carboxylic | Silicon | Other | Temperature | Time |
| Example No. | Alkali | acid | compound | additives | (° C.) | (minutes) |
| 1 | KOH | None | None | None | 80 | 20 |
| | 7.5% | | | | | |
| 2 | KOH | None | K₂SiO₃ | None | 80 | 20 |
| | 7.5% | | 2.5% | | | |
| 3 | KOH | None | None | IPA 5% | 80 | 20 |
| | 7.5% | | | | | |
| 4 | KOH | None | None | None | 80 | 60 |
| | 1% | | | | | |
| 5 | KOH | None | None | None | 70 | 5 |
| | 30% | | | | | |
| 6 | NaOH | None | None | None | 80 | 20 |
| | 8% | | | | | |
| 7 | None | Hexanoic | None | None | 80 | 20 |
| | | acid(C6) | | | | |
| | | 5% | | | | |
| 8 | None | Hexanoic | K₂SiO₃ | None | 80 | 20 |
| | | acid(C6) | 15% | | | |
| | | 5% | | | | |

TABLE 4

| Comparative | | | | | | |
|---|---|---|---|---|---|---|
| Example | Reflectance (%) | | | | | |
| No. | 430 nm | | 600 nm | | 760 nm | |
| 1 | 33.0 | 26.4 | 30.1 | 29.2 | 36.4 | 28.4 |
| 2 | 30.6 | 27.8 | 28.3 | 27.8 | 33.4 | 36.3 |
| 3 | 15.8 | 18.8 | 15.0 | 17.4 | 19.5 | 19.3 |
| 4 | 29.7 | 32.2 | 22.2 | 25.6 | 31.1 | 25.6 |
| 5 | 29.1 | 31.7 | 26.4 | 25.5 | 38.1 | 35.4 |
| 6 | 18.5 | 17.9 | 17.1 | 16.6 | 19.0 | 21.4 |
| 7 | 20.1 | 20.3 | 18.5 | 18.4 | 21.3 | 24.1 |
| 8 | 22.1 | 20.1 | 19.9 | 18.3 | 22.0 | 23.9 |

### Experimental Example 1

An etching treatment was performed in the same manner as in Example 1 except that a single crystal silicon wafer (a square 126 mm on a side) was used instead of a polycrystalline silicon wafer, and then reflectance measurement was performed. A reflectance at 430 nm was 5.9%, a reflectance at 600 nm was 2.5%, and a reflectance at 760 nm was 6.5%.

As shown in FIGS. 1 and 2, in Example 1 where the etching solution of the present invention was used, a texture was uniformly formed except for a (111) plane portion. In contrast, in Comparative Example 1 where the etching solution containing only an alkali was used, texture formation was entirely insufficient, and a large number of flat portions were observed.

In addition, as shown in Table 2, the reflectances of the polycrystalline silicon wafers obtained in Examples 1 to 21 were each comparable to that of the single crystal silicon wafer of Experimental Example 1, and showed small variations. On the other hand, in Comparative Examples 1 to 8 where the etching solutions differing from the etching solution used in the method of the present invention in composition were used, high reflectances were obtained at each wavelength, and variations were large.

Accordingly, the etching solution of the present invention was found to be effective for a polycrystalline silicon wafer.

1. A method of producing a polycrystalline silicon substrate, comprising etching a polycrystalline silicon substrate with an alkaline etching solution containing at least one kind selected from the group consisting of a carboxylic acid having 1 or more and 12 or less carbon atoms and each having at least one carboxyl group in one molecule, and salts of the acids, to thereby form an uneven structure on a surface of the polycrystalline silicon substrate.

2. A method of producing a polycrystalline silicon substrate according to claim 1, wherein the etching solution contains silicon.

3. A method of producing a polycrystalline silicon substrate according to claim 2, wherein the etching solution contains silicon at a 0.5 mass % concentration to a saturated concentration.

4. A method of producing a polycrystalline silicon substrate according to claim 2, wherein the etching solution is prepared by dissolving one or more kinds of silicon selected from the group consisting of metal silicon, silica, silicic acid, and silicate in advance.

5. A method of producing a polycrystalline silicon substrate according to claim 1, wherein the carboxylic acid is at least one kind selected from the group consisting of acetic acid, propionic acid, butanoic acid, pentanoic acid, hexanoic acid, heptanoic acid, octanoic acid, nonanoic acid, decanoic acid, undecanoic acid, dodecanoic acid, acrylic acid, oxalic acid, citric acid, malic acid, and cyclopentane dicarboxylic acid.

6. A method of producing a polycrystalline silicon substrate according to claim 1, wherein the carboxylic acids have 2 or more and 8 or less carbon atoms.

7. A method of producing a polycrystalline silicon substrate according to claim 1, wherein the etching solution has a carboxylic acid concentration of 0.2 to 80 mass %.

8. A polycrystalline silicon substrate comprising an uneven structure on a surface thereof, the substrate being produced by the method according to claim 1.

9. A polycrystalline silicon substrate according to claim 8, wherein the substrate is used as a semiconductor substrate for a solar cell.
